(19) United States
(12) Patent Application Publication
(10) Pub. No.: US 2013/0006567 A1
(43) Pub. Date: Jan. 3, 2013

(54) METHOD AND APPARATUS FOR SCHEDULING A USE OF TEST RESOURCES OF A TEST ARRANGEMENT FOR THE EXECUTION OF TEST GROUPS

(76) Inventor: Wolfgang Horn, Stuttgart (DE)

(21) Appl. No.: 13/516,696

(22) PCT Filed: Dec. 15, 2009
(86) PCT No.: PCT/EP2009/067212

§ 371 Date: Sep. 13, 2012

(51) Int. Cl. G01R 31/00

(52) U.S. Cl. 702/108

(57) ABSTRACT

A method for scheduling a use of test resources comprises obtaining an assignment of a test resource to each test group of a test flow. The test flow comprises an initial execution order. The method comprises checking for a resource conflict between an assignment of a test resource to a given test group in a test flow and an assignment of other test resources to other test groups and test flows. The other test groups are scheduled for a temporally overlapping execution with the given test group. The method comprises manipulating the test flow execution order of the test groups. The resource conflict is eliminated by performing a swap between a test group associated with the resource conflict in a test flow with a higher priority compared to a time-interval-insertion in combination with a movement, and moving the test group associated with the resource conflict to an inserted time interval.

### CROSS-REFERENCES TO RELATED APPLICATIONS

This application is a Continuation of and claims priority to International Application No. PCT/EP2009/067212, filed on Dec. 15, 2009, titled “METHOD AND APPARATUS FOR SCHEDULING A USE OF TEST RESOURCES OF A TEST ARRANGEMENT FOR THE EXECUTION OF TEST GROUPS,” by Horn, et al., which is herein incorporated by reference.

### TECHNICAL FIELD

Embodiments of the present invention relate to scheduling the use of test resources of a test arrangement for the execution of test groups and to scheduling test resources. In particular, embodiments of the present invention relate to scheduling a use of test resources of a semiconductor test arrangement or test system for the execution of test groups.

### BACKGROUND

In testing devices or products, e. g. after production, it is crucial to achieve among others a high product quality, an estimation of the device or product performance, a feedback concerning the manufacturing process and finally a high customer contentment. Usually a plurality of tests is performed in order to ensure the correct function of a device or product. The plurality of tests may be compiled in a test flow wherein the test flow may be separated into different test suites or test groups which contain one or more tests for testing the device or product. For example, a semiconductor device may be tested with a test flow comprising contact tests, current-voltage tests, logic tests, speed tests, stress tests and functional tests. A test flow may assume a fixed sequence of test suite or test group execution. In other words, test suites may be performed in a certain temporal order or sequence.

Since testing a semiconductor device or a product, in general, may be quite expensive in terms of capital cost for required test equipment and cost in terms of required test time, testing of a device or product should be performed in an efficient way. Therefore, devices are often tested in parallel to reduce test time. On the other hand, an increased parallel testing often requires a high number of test resources of a test arrangement. The growing number of devices being tested in parallel, and the limited availability of some expensive test equipment resources may become a major cost contributor to, for example, IC vendors. The limited availability of certain types of test equipment may be caused by the high capital cost of such test systems or because of the limited availability in terms of the form factor of the test equipment. Test resources which are required for testing a device must either be available per device (with associated high capital costs) or tests requiring these resources are serialized, such that a longer test time may be required and therefore also possibly higher costs as well. It should be noted that during testing each test does not always make use of all the test resources available from a test arrangement. Therefore, the need for scheduling test resources of a test arrangement in an efficient and favorable way is desirable.

### SUMMARY OF THE INVENTION

Embodiments of this present invention provide solutions to the challenges inherent in scheduling testing resources of a test arrangement when executing test groups. In a method according to one embodiment of the present invention, a method for scheduling a use of test resources of a test arrangement for the execution of test groups is disclosed. The described improvements may relate to a manner in how test groups in test flows for testing devices under test (DUT) in parallel are reordered, such that test resources of a test arrangement may be applied in a more efficient way.

In a method according to one embodiment of the present invention, a method for scheduling a use of test resources of a test arrangement for the execution of test groups may comprise a step of obtaining an assignment of a test resource of the test arrangement to each test group of a test flow for testing a device under test (DUT) using the test arrangement. The method may further check whether there is a resource conflict between an assignment of a test resource to a test group and another test group of the test flows for testing devices under test in parallel and by manipulating the execution order of a test group in the test flow in a predetermined way to eliminate the resource conflict.

In a method according to one embodiment of the present invention, the manipulation of the execution order of test groups in a test flow may be performed in subsequent steps comprising swap-operations, time-interval-insert-operations in combination with move-operations or move-to-empty-time-interval-operations.

In a method according to one embodiment of the present invention, in swap-operation embodiments, the time-interval-insert-operation in combination with the move-operation and the move-to-empty-time-interval-operation is performed in a prioritized way so that the test time for performing tests and the allocation of the test resources required to perform the tests, can be optimized.

### BRIEF DESCRIPTION OF THE DRAWINGS

Embodiments of the present invention will be better understood from the following detailed description, taken in conjunction with the accompanying drawing figures in which like reference characters designate like elements and in which:

FIG. 1 illustrates an exemplary flow diagram, illustrating the steps to a method for scheduling test resources of a test arrangement in accordance with an embodiment of the present invention;

FIG. 2A illustrates an exemplary block diagram illustrating a process for scheduling test resources of a test arrangement in accordance with an embodiment of the present invention;

FIG. 2B illustrates an exemplary block diagram illustrating a process for scheduling test resources of a test arrangement in accordance with an embodiment of the present invention;

FIG. 3 illustrates an exemplary block diagram illustrating an ineffective schedule of test resources of a test arrangement;

FIG. 4 illustrates an exemplary block diagram illustrating the optimized schedule of test resources for the example in FIG. 3, in accordance with an embodiment of the present invention;

FIG. 5 illustrates an exemplary pseudo-code for performing a process for scheduling test resources of a test arrangement in accordance with an embodiment of the present invention;

FIG. 6A illustrates an exemplary scheme for an initial assignment of test resources of a test arrangement to test groups in a test flow in accordance with an embodiment of the present invention;

FIG. 6B illustrates an exemplary schematic arrangement of the devices under test, the corresponding test groups arranged in a matrix arrangement, and process step for searching a resource conflict in accordance with an embodiment of the present invention;

FIG. 6C illustrates an exemplary process step of searching a non-conflicting column within the matrix arrangement of the test groups in accordance with an embodiment of the present invention;

FIG. 6D illustrates an exemplary process step for searching a resource conflict within a single column of the matrix arrangement in accordance with an embodiment of the present invention;

FIG. 6E illustrates an exemplary process step for searching a non-conflicting column in the matrix arrangement of the test groups in accordance with an embodiment of the present invention;

FIG. 6F illustrates an exemplary process step for searching a resource conflict in another single column of the matrix arrangement in accordance with an embodiment of the present invention;

FIG. 6G illustrates an exemplary process step for searching a non-conflicting column and swapping the execution order of the respective test groups in the matrix arrangement in accordance with an embodiment of the present invention;

FIG. 6H illustrates an exemplary process step for searching a conflict within a single column in accordance with an embodiment of the present invention;

FIG. 6I illustrates an exemplary process step for searching a non-conflicting column and swapping the execution order of the respective test groups in accordance with an embodiment of the present invention;

FIG. 6J illustrates an exemplary final test matrix arrangement of the test groups with all resource conflicts removed in accordance with an embodiment of the present invention; and

FIG. 7 illustrates an exemplary block diagram of an apparatus for scheduling test resources of a test arrangement in accordance with an embodiment of the present invention.

### DETAILED DESCRIPTION

Reference will now be made in detail to the preferred embodiments of the present invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of embodiments of the present invention, numerous specific details are set forth in order to provide a thorough understanding of the present invention. However, it will be recognized by one of ordinary skill in the art that the present invention may be practiced without these specific details. In other instances, well-known methods, procedures, components, and circuits have not been described in detail so as not to unnecessarily obscure aspects of the embodiments of the present invention. The drawings showing embodiments of the invention are semi-diagrammatic and not to scale and, particularly, some of the dimensions are for the clarity of presentation and are shown exaggerated in the drawing Figures. Similarly, although the views in the drawings for the ease of description generally show similar orientations, this depiction in the Figures is arbitrary for the most part. Generally, the invention can be operated in any orientation.

### Notation and Nomenclature:

Some portions of the detailed descriptions, which follow, are presented in terms of procedures, steps, logic blocks, processing, and other symbolic representations of operations on data bits within a computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “processing” or “accessing” or “executing” or “storing” or “rendering” or the like, refer to the action and processes of a computer system, or similar electronic computing device, that manipulates and transforms data represented as physical (electronic) quantities within the computer system's registers and memories and other computer readable media into other data similarly represented as physical quantities within the computer system memories or registers or other such information storage, transmission or display devices. When a component appears in several embodiments, the use of the same reference numeral signifies that the component is the same component as illustrated in the original embodiment.

Embodiments of this present invention provide solutions to the increasing challenges inherent in scheduling testing resources of a test arrangement when executing a plurality of test groups. As described herein, various embodiments of the present disclosure provide test time reductions, as well as test resource reductions and/or testing resource optimization. Therefore, testing may be optimized and made more efficient compared to conventional test approaches.

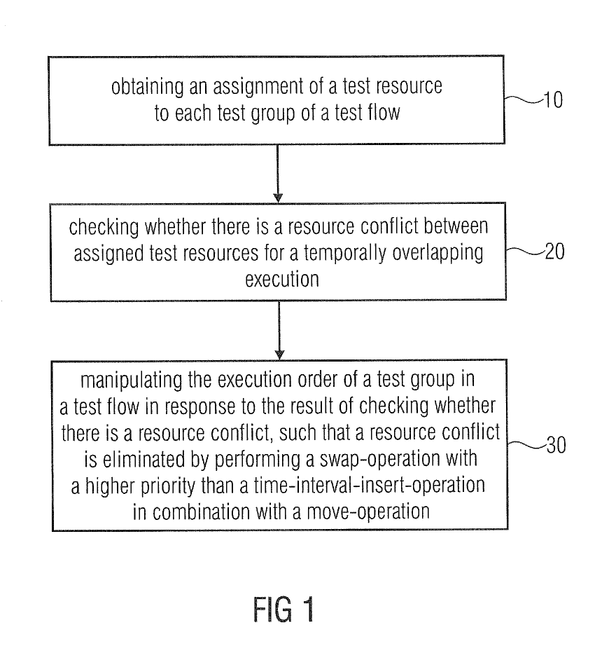

FIG. 1 illustrates an exemplary flow chart of a method for scheduling a use of test resources of a test arrangement for the execution of test groups. The method illustrated in FIG. 1 comprises the following steps. In step 10 of FIG. 1, an assignment is obtained of a test resource of the test arrangement to a test group of a test flow for testing a device under test (DUT) using the test arrangement. In one embodiment, the test flow may comprise an initial execution order of the test groups. In step 20 of FIG. 1, the method checks whether there is a resource conflict between an assignment of a test resource to a test group in a test flow and an assignment of one or more test resources to another test group in another test flow. Such resource conflicts may exist when the other test group is scheduled for temporally overlapping execution with the test group using the same test arrangement. In one embodiment, the test flows for different DUTs may be the same test flows. In other words, they may comprise identical test groups with the same time intervals, or the test flows may be different test flows, for example, for testing different DUTs, but with the same test arrangement. In response to a result of checking whether there is a resource conflict, in step 20 of FIG. 1, the method continues to step 30 of FIG. 1. In step 30, an execution order of a test group in a test flow is manipulated such that the resource conflict is eliminated.

As discussed herein, potential resource conflicts can be eliminated by performing a swap-operation of the test group associated with the resource conflict within the test flow. The swap-operation of the test group in a test flow may be performed with a higher priority compared to a so called time-interval-insert-operation in combination with a move-operation. In one embodiment, a time-interval-insert-operation inserts a new time interval into a test flow for a test group. A time interval may act as a placeholder for a test group, and the move-operation may be performed by moving a test group associated with the resource conflict to a time interval, which is created by the time-interval-insert-operation in a test flow.

In other exemplary embodiments, a method for scheduling a use of test resources of a test arrangement for the execution of test groups may be performed in order to increase the efficiency or to optimize test resource allocation of a test arrangement for testing devices. The devices or products to be tested are generally named devices under test (DUTs). Such DUTs can be, for example, semiconductor devices, optical devices, electronic devices or electronic circuitry, but also other products as mechanical parts, consumer products in general, as well as, other goods, for example, in the field of automotive, chemistry, mechanical engineering, food production, medical engineering etc. Although the following embodiments mostly refer to testing semiconductor devices, the embodiments should not be considered as narrowing, since exemplary embodiments of a method for scheduling test resources of a test arrangement and exemplary embodiments of an apparatus for scheduling test resources of test arrangements may also be applied for scheduling test resources in other technical fields.

An exemplary test arrangement may comprise different test resources. A test arrangement may comprise, for example, one (semiconductor) or more tester or one or more test systems which can be linked or grouped together. A test arrangement may be used for testing at least two devices under test in parallel or at least in temporally overlapping time intervals. This means that, for example, a first and a second device under test may be tested with a test arrangement at the same time or at least partly at the same time. A first device under test may be tested first and while the first device under test is tested a second device under test may also be tested using the same test arrangement.

Each test arrangement may comprise a certain number of test resources. An exemplary test resource may be a certain instrument, for example, a measurement instrument in a tester or test system that is part of the test arrangement. In the case of a semiconductor test system or test arrangement such a test resource may be, for example, an arbitrary waveform generator, a digitizer, one or more device power supply channels, a radio frequency (RF) instrument, as well as, a certain number of analog and/or digital channels. A test arrangement may comprise a certain number of test resources which are scheduled in an effective way so that the test resources for testing at least two devices under test in at least partly overlapping time intervals are scheduled in an effective way to reduce on one hand the test time and on the other hand the required test resources.

The definition of a test resource is flexible and is not restricted to a certain physical type of test resource, but may also involve a certain group of physical test resources. This means, for example, that an arbitrary waveform generator, a digitizer and, e.g. three digital channels may be considered or grouped together as a test resource. The term test resource may be adapted to the need for testing devices under test with a test arrangement. In general a test resource may comprise a minimal and a maximal granularity. The granularity may depend on a necessary parallel usability of test resources. Further, it should be noted, that a test flow may comprise a sub flow. A sub flow may have a fixed execution order so that no reordering within the sub flow need take place. This means the time intervals for respective test groups forming the sub flow should not be changed. Such a sub flow may also comprise a fixed execution order within the respective test flow, so that the time interval position of the sub flow within the test flow will not be changed. An exemplary sub flow may comprise one or more test groups as described therein.

According to step 10 of FIG. 1, an assignment of a test resource to a test group of a test flow for testing a device under test using the test arrangement may be obtained. A test arrangement as described herein may comprise different test resources. In step 10 of FIG. 1, test resources of a test arrangement may be assigned to certain test groups of a test flow for testing a DUT. An assignment of test resources to test groups in a test flow may be considered as specifying a start configuration of the test groups with the assigned test resources. Such an assignment of test resources may be externally achieved, for example, by a skilled person, e.g. a technician or a (test-) engineer or it may be defined by an additional algorithm. Therefore, step 10 of FIG. 1, obtaining such an assignment can comprise both possibilities—to obtain such an assignment external or by applying an internal algorithm. The assignment of resources to test groups may require an additional algorithm in case there is more than one resource of the same type which can be freely assigned to any DUT site. A simple exemplary algorithm may assign the instances of such a resource, for example, in a round-robin fashion. This means, in an exemplarily embodiment, such an algorithm for assigning test resources to test groups could be the round-robin algorithm, which may assign in circular order the test resources RX1 to RXn to test groups for testing DUT 1 to DUT N.

Schematically, this is illustrated in the following expressions. DUT 1→RX1, DUT 2→RX2, . . . , DUT n→RXn; DUT n+1→RX1, DUT n+2→RX2, . . . , DUT 2*n→RXn; . . . ; DUT m*n+1→RX1,. . . , DUT→RX(N−(m*n)).

A test group may comprise at least one test which is performed for testing a DUT. The test flow determines the test groups and their execution order for testing the DUTs. A test flow comprises an initial execution order of the test groups. Each test group may comprise at least one test which requires at least one test resource of the test arrangement at a certain time. Since the number of test resources of a test arrangement is limited, the number of test groups with an assigned certain test resource which can be run in parallel or in at least partly overlapping time periods or intervals is limited as well. This means, that on a test arrangement only a limited number of DUTs can be tested in parallel or in overlapping time intervals. Depending on the test resources, e.g. test channels which are available by a test arrangement, semiconductor devices—DUTs—may be tested, for example, 32-fold, 64-fold, or 128-fold parallel. Each device under test which may be tested in parallel in overlapping time periods with a test arrangement may comprise its own test flow with its own test groups and execution sequence. This means scheduling a use of test resources of a test arrangement is not limited to identical DUTs and it is also not limited to test DUTs with the same test flow and the same test groups. In general, the test arrangement may be used to test a plurality of identical or different devices under test with identical or different test flows comprising identical or different test groups with assigned test resources of the test arrangement. The test flows of the different devices under test may start at different times, may be interrupted at different times or may start and stop at the same or different times. The test flows may run at least partly at the same time on the same test arrangement.

After obtaining an assignment, as illustrated in step 10 of FIG. 1, of a test resource to each test group (which means each test group for testing a device under test using the test arrangement has an assigned test resource of the test arrangement) the step of checking whether there is a resource conflict, as illustrated in step 20 of FIG. 1, between two assignments of test resources to test groups is performed. In exemplary embodiments, scheduling a use of test resources of a test arrangement comprises checking whether there is a resource conflict between an assignment of a test resource to a first test group in a test flow with another assignment of one or more test resources to a second test group scheduled in another test flow, so that a temporally overlapping execution with a test group using the test arrangement takes place.

According to embodiments herein, a resource conflict is given if the number of test groups with an assignment of an identical test resource, which are scheduled in temporally overlapping execution time intervals is higher than the number of identical test resources, which are available in the test arrangement for a temporally overlapping execution. This means, for example, that if a test arrangement can allocate only three test resources of type RA at the same time, a resource conflict will exist if more than three test resources are assigned to test groups within temporally overlapping time intervals. In this case, the execution order of one of the test groups may be shifted within the test flow to a time interval or time position where no resource conflict occurs. In other words, a resource conflict is given if the number of allocatable test resources in certain overlapping test time intervals is lower than the number of the same test resources which are required for testing the DUTs in the same overlapping test time intervals.

A test resource, as described herein, may be connectable or coupled, e.g. physically, electrically, mechanically, optically or however necessary for a test in a test group to a plurality of DUTs. However, in exemplary cases a test resource may be considered an individual test resource that may be individually allocated by the test resource assignment only to test groups or tests for DUTs that are connectable to the specific test resource. Therefore, test resources may be individual test resources or dynamical test resources which can be connected or coupled to different DUTs.

According to the method for scheduling a use of test resources of a test arrangement, as illustrated in FIG. 1, in response to the result of checking whether there is a resource conflict, in step 20 of FIG. 1, manipulating the execution order of a test group in a test flow is performed, as illustrated in step 30 of FIG. 1. Manipulating may be performed such that a resource conflict is eliminated by performing a swap-operation between a test group associated with a resource conflict in the assigned test flow. The swap-operation may be performed with a higher priority compared to a time-interval-insert-operation in combination with a move-operation. An exemplary swap-operation can be performed if a test group associated with a resource conflict is swapped within a test flow with another test group so that the execution order of both test groups is exchanged and based on the exchange or manipulation of the test groups, the respective resource conflict can be eliminated.

According to exemplary embodiments, a swap-operation may be performed; however, a new resource conflict may develop at new positions of the test groups in the test flow. Therefore, a preceding step of checking whether there is a resource conflict if both test groups are swapped to the respective time intervals in the test flow is performed, as illustrated in step 20 of FIG. 1. If there is a new resource conflict, the swap-operation is not performed, but if there is no new resource conflict and the old resource conflict is eliminated by swapping the test groups within the test flow, the swap-operation is performed.

With a lower priority a time-interval-insert-operation may be performed if, for example, the swap-operation cannot be performed because at all possible time interval positions a new resource conflict would occur. In this case, an empty time interval may be inserted in a test flow and the test group associated with the resource conflict may be shifted in a subsequent move-operation to the inserted time interval. Therefore, a resource conflict can be solved or eliminated by increasing the time required to complete a test flow by inserting a new time interval into the test flow and moving a test group associated with the resource conflict to this inserted time interval. The test time interval may be inserted into different positions within the test flow. Such an exemplary insertion of new time intervals according to the invention does not increase the overall test time when compared to a non-optimized, conventional method for scheduling a use of test resources which may require a serialization of those test resources.

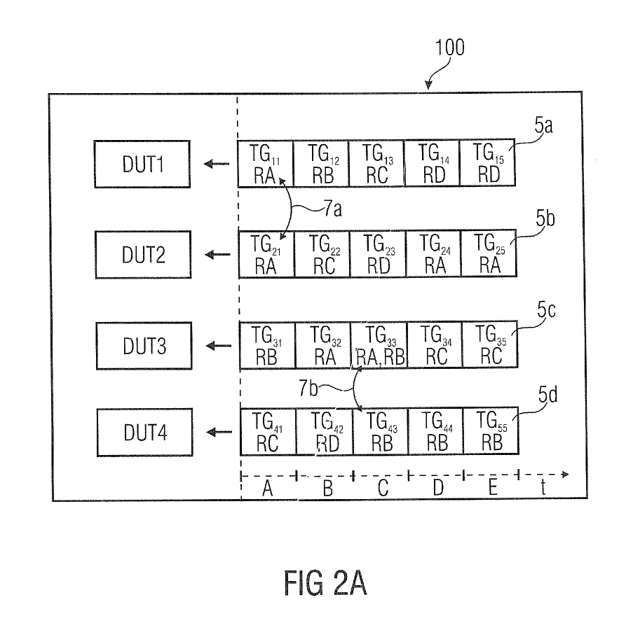

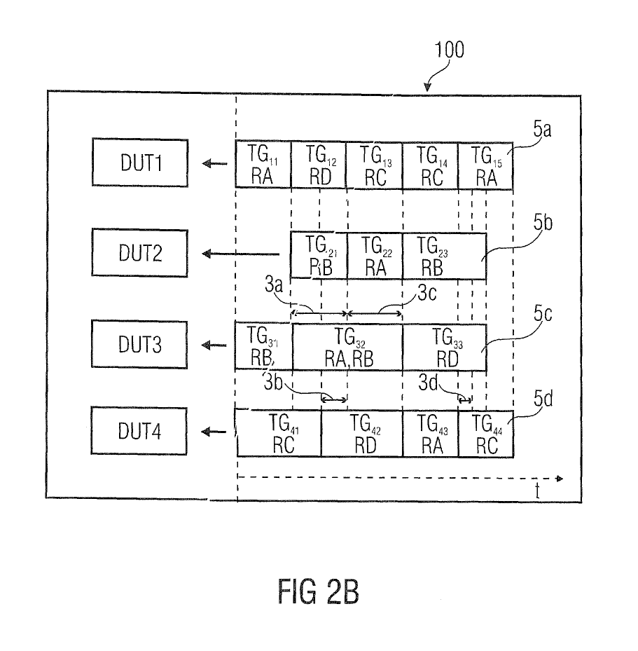

In FIG. 2A a schematic block diagram is depicted for illustrating a relation between a test arrangement 100 and the devices under test (DUT 1,2,3,4) which are tested using the test arrangement 100. Each DUT 1,2,3,4 may be tested with its respective test flow. Therefore, as illustrated in FIG. 2A, DUT 1 is tested with test flow 5a, DUT 2 with test flow 5b, DUT 3 with test flow 5c and DUT 4 with test flow 5d.

According to exemplary embodiments of the invention, the DUTs being tested may be identical or different DUTs. The DUTs may be, for example, different types of semiconductor devices, or they may all be the same type of semiconductor device. Each test flow 5a,b,c,d comprises a certain number of test groups TGs. Each test group TGᵢⱼ comprises in this embodiment one or more assigned test resources RA, RB, RC or RD. Each test flow 5a,b,c,d also comprises an initial execution order of the test groups within the respective test flow. In this example, the test flow 5a may comprise the execution order TG₁₁ followed by TG₁₂, followed by TG₁₃, followed by TG₁₄, and finally TG₁₅. Each test group may require a certain test time or time interval. In this embodiment the time interval required by the test groups may be identical. In FIG. 2A, a schematic time line t is shown comprising test time intervals A, B, C, D, and E. According to this embodiment all four DUTs are tested, starting at the same time and each test group comprises the same test time interval period or length, i.e. the same test time. In addition, the number of test groups within the test flows is identical. Each test group TG comprises at least one test for testing the respective DUT. All test groups in the time interval A (TG₁₁ TG₂₁, TG₃₁, and TG₄₁) are performed in parallel or in temporally overlapping execution order. The same is true for the test groups TG₁₂, TG₂₂, TG₃₂, and TG₄₂, which are running in parallel during the time interval B and so forth.

Depending on the test resources, which are available in the test arrangement during a certain time interval, a resource conflict may occur. For example, in FIG. 2A, the test arrangement 100 may allocate a per time interval to only one test resource RA, RB, RC and RD. Therefore, during a time interval A a resource conflict occurs between the test group TG₁₁ and TG₂₁ since both test groups require the test resource RA for a temporally overlapping execution during time interval A. The test group TG₃₃ for testing the DUT 3 with the test flow 5c in the test time interval C may require two test resources RA and RB for performing the tests. As illustrated in FIG. 2A, the test arrangement 100 makes each test resource available only one time per time interval. Therefore, there is still another resource conflict between test group TG₃₃ and test group TG₄₃ in time interval C, since both test groups require test resource RB at the same time interval. As described herein, such resource conflicts may be solved so that test time duration and/or the number of required test resources can be optimized.

As illustrated in step 30 of FIG. 1, an execution order of test groups may also include physically completing electrical connections or switching out test instruments or test resources to devices under test, e.g. on a load board for a test system. In other words, exemplary embodiments may require electrically connecting or disconnecting at certain time intervals, certain test resources of a test arrangement with the devices under test. Manipulating the execution order of a test group may include switching, e.g. a relay, for connecting or disconnecting test resources to a device under test, or it may also comprise applying and/or measuring test signals or device signals at a certain time in the test flow. The test arrangement may also be configured to evaluate device signals received from a DUT. According to further embodiments, it is also possible to simply disconnect and swap DUT sites instead of switching the test resources—though in the case of semiconductor testing this may involve more time, to disconnect electrical connections, mechanical swapping, electrical connections to the replacement DUT, and settling times for the DUTs, than a serialization of the tests to be performed. But for non-semiconductor testing with longer test times compared to typical semiconductor tests (some milliseconds to minutes) this above mentioned approach may be useful.

According to one embodiment there is an exemplary method for testing a plurality of devices under test, by executing the method for scheduling a use of test resources of a test arrangement as described herein, and further comprising an additional step of electrically connecting and/or disconnecting the plurality of devices under test to test resources of the test arrangement based on the execution order of the test groups in the test flows after executing the method for scheduling a use of test resources.

The test arrangement may comprise test resources which are configured to perform a test for a device under test by applying a test signal or a supply signal and/or to receive a device signal from the device under test. The test arrangement may be configured to evaluate the device signal from the device under test to determine whether the device under test is passing the test or failing the test.

FIG. 2B illustrates an exemplary embodiment for illustrating a relation between a test arrangement, devices under test, test flows with test groups, assigned test resources and overlapping time intervals. According to the exemplary embodiment of FIG. 2B, a test arrangement 100 may be used for testing four devices under test DUT 1,2,3,4. Each device may be tested with a corresponding test flow 5a,b,c,d. In this embodiment the test flow 5b for testing the DUT 2 starts later compared to the other test flows 5a,c,d and stops earlier than test flows 5a and 5b, as can be seen at the time line t in FIG. 2B. Therefore, duration of the test flows which are running on the test arrangement 100 and also a number of test groups in the different test flows can be different. In this embodiment the test flow 5a comprises five test groups TG₁₁, TG₁₂, TG₁₃, TG₁₄ and TG₁₅, while the test flow 5b comprises only three test groups TG₂₁, TG₂₂ and TG₂₃. As also illustrated in FIG. 2B, the duration or time period of the individual test groups may be different. For example, the duration of test group TG₃₂ may be longer than the duration of the test group TG₂₁.

As illustrated in FIG. 2B, the time intervals of the different test groups TG may overlap for different time periods or durations. The test arrangement 100 may be able to allocate each test resource RA, RB, RC, and RD only one time in a test time interval or at one point in time. As a consequence, there may be resource conflicts between test groups TG which are scheduled for a temporally overlapping execution using the same test resources.

For example, both test groups TG₂₁ and TG₃₂ require during an overlapping time interval 3a test resource RB and, hence, a resource conflict is given between both test groups. Also, the test group TG₁₂ and the test group TG₄₂ require the same test resource RD in an overlapping time interval 3b, so that a further resource conflict is given within the current scheduling of test resources. Furthermore, the test group TG₃₂ may be in conflict with the test group TG₂₂ because of the test resource RA, which is also scheduled in an overlapping time interval 3c. Finally, a fourth resource conflict is depicted in FIG. 2B between the test group TG₁₅ and the test group TG₄₃ within a small overlapping time interval 3d.

In one exemplary embodiment, the time interval of conflicting test groups may comprise a different time period or duration. The overlapping time interval which causes a resource conflict may comprise just a single point in time or the time intervals of at least two test groups associated with a resource conflict may partly or completely overlap. The test groups may be executed at the test arrangement in parallel.

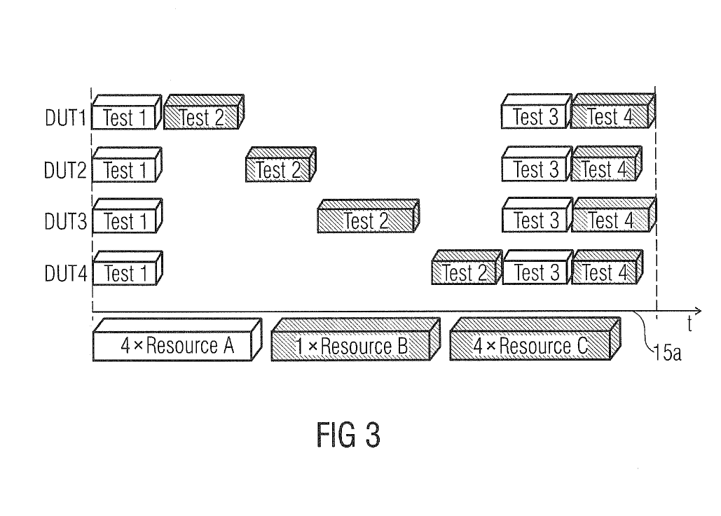

FIG. 3 illustrates an exemplary block diagram for testing four devices under test DUT 1,2,3,4. In this embodiment, a test arrangement may comprise four times the test resource A, one times the test resource B, and four times the test resource C. The test resources are not scheduled in an optimized manner, since the overall test time in this embodiment is quite high because of the serialized execution of test 2. In current test flows test groups or tests often assume a fixed execution order or time sequence on a time line t.

The resource A may be allocated by the test arrangement in four overlapping time intervals, and the corresponding test 1 can run in parallel on all four devices under test DUT 1,2,3,4. In this example, the test resource B is a bottleneck, since it can only be allocated to one test group during a certain time interval. As a consequence, current test flows assume a fixed serialized test suite execution. Therefore the execution of test 2 by means of test resource B is serialized. Such a serialization can be quite time consuming, and should therefore be avoided. The first test 2 is applied to DUT 1, then to DUT 2 and after finishing DUT 2, the DUT 3 and DUT 4 devices are tested in subsequent time intervals. As a consequence of the serial testing the overall test time is increased and therefore it is time and cost expensive. By reordering the test flows per device under test the test resource needs may be optimally balanced. If there are enough independent test suites or test groups that can be run in any order within a test flow, tests which are using expensive resources may be run in parallel with other tests using different test resources. The need for test resources available per device may even be reduced as well.

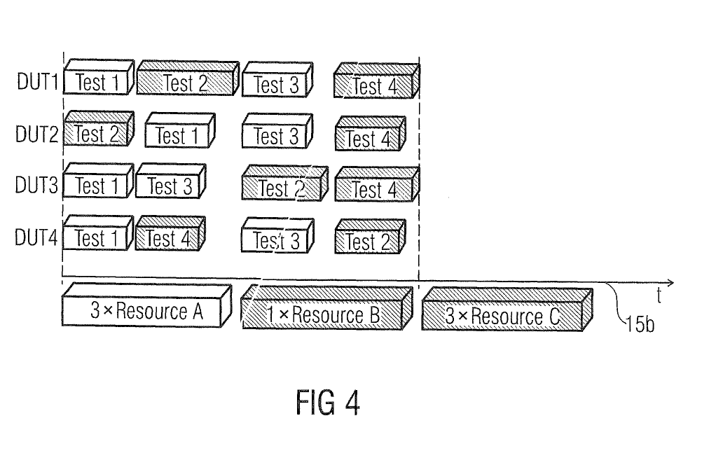

FIG. 4 illustrates an exemplary optimized execution order for the tests or test groups illustrated in FIG. 3. According to one embodiment of the present invention, the test flow may include test suits or test groups arranged in a certain execution order. For a desired test flow reordering, test suites or test groups may be grouped into independent sub-flows that can be executed in any order. A test flow may comprise a set of test groups TG with an initial execution order of the test groups:

testflowᵢ={TGᵢ₁, . . . , TGᵢₙ} (1)

For each test group TGᵢ the set of required exclusive test resources is

known: R(TGᵢ)={Ri₁. . . , Rᵢₘ} (2)

This means each test group may comprise a set of test resources which are required for testing the respective device under test. For each device under test Di (i=1, . . . , N) the set of test groups may be different and may have different lengths. It is not presumed that the devices are of the same type.

Any two test groups i and j are said to be conflicting if:

R(TGᵢ) ∩ R(TGⱼ)≠Ø short: TGᵢ⋄ TGⱼ (3)

The test group TGᵢₖ is said to be conflicting with column c if:

$${⋃}_{{j = 1 , … , N}_{j \neq i}} R ( {TG}_{jc} ) ⋂ R ( {TG}_{ik} ) \neq ∅ short \text{:} {TG}_{ik} ◇ c ) \qquad ( 4 )$$

It should be noted that exemplary embodiments of methods for scheduling a use of test resources of a test arrangement for the execution of test groups or steps thereof can be implemented as a computer program. Depending on certain implementation requirements, exemplary embodiments may be implemented in hardware or in software. Implementation may be performed using a digital storage medium, in particular, a disc, a DVD, a CD or a Blu-ray disc having electronically readable control signals, which cooperate with programmable computer systems such that the exemplary methods are performed. Generally, embodiments of the present invention may include a computer program product with a program code stored on a machine readable carrier, the program code being operated for performing the exemplary methods as a computer program on a computer.

The following exemplary embodiments are merely illustrative to illustrate the principals of the present invention. It is understood that modifications and variations of the matrix arrangement, described below, and the steps for performing the exemplary methods will be apparent to others skilled in the art. In general no such matrix arrangement is necessary and the described methods, algorithms and formulae can be performed without using such a matrix arrangement. The arrangement of test groups and DUTs in a matrix is just a tool for making the methods and the algorithm more descriptive. It is the intent, therefore, to be limited only be the scope of the pending patent claims and not by the specifically details presented by way of illustration, description and explanation of the embodiments therein.

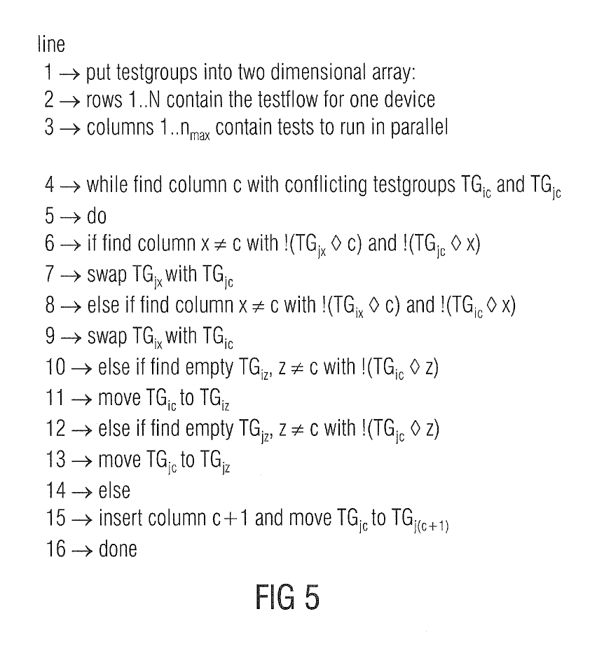

FIG. 5 illustrates an exemplary pseudo-code for a computer program for the method for scheduling a use of test resources of a test arrangement according to an embodiment of the present invention. The step of obtaining an assignment of a test resource to a test group of a test flow may comprise logically arranging each test group with its assigned test resource in a matrix arrangement, such that the test groups form rows and test groups, which are scheduled for at least partly temporally overlapping execution using the test arrangement, form columns of the matrix arrangement. As a consequence, according to this illustrative embodiment each test group comprises a column position and a row position in the matrix arrangement. As illustrated in line 1 of FIG. 5, the test groups are arranged in a two dimensional array wherein each row 1 . . . N comprises the test flow for one device under test and the columns 1 . . . nₘₐₓ of the two dimensional array or matrix arrangement contain tests to run in parallel or in temporally overlapping time intervals. The number of columns of the matrix arrangement may determine the number of time intervals in a test flow for testing a device under test.

As illustrated in exemplary embodiments described herein, obtaining an assignment, as illustrated in step 10 of FIG. 1, may include receiving an assignment of a test resource of the test arrangement to a test group of the test flow for testing a device under test using the test arrangement. The test flow may comprise an initial execution order of the test groups. According to other embodiments, the step of obtaining, as illustrated in step 10 of FIG. 1, may comprise an active assigning of a test resource to a test group of a test flow for testing a device under test using the test arrangement. In other words, the obtaining in step 10 may be performed so that an assignment of a test resource to a test group of a test flow is fed to an exemplary computer program, for example, and the computer program performs the steps of checking whether there is a resource conflict and manipulating the execution order of a test group in a test flow in response to the result of checking whether there is a resource conflict, as illustrated in FIG. 1. According to other embodiments, the obtaining may be performed so that, for example, a computer program may calculate or actively assign to each test group of a test flow for testing the device under test the tests resources of a test arrangement.

After arranging the test groups into a two dimensional array or a matrix arrangement, each test group TG comprises a row position and a column position. An exemplary test group TG_{ic}, comprises a row index i=1 . . . N, and a column index c=1 . . . nₘₐₓ. As noted herein, in one embodiment, a logical arrangement may be chosen such that test groups of test flows for testing devices using a test arrangement may form columns of a matrix arrangement, and the test groups which are scheduled for temporally overlapping execution using the test arrangement are also forming rows of the matrix arrangement.

As illustrated in FIGS. 1 and 5, checking whether there is a resource conflict can be performed column-by-column or row-by-row. Therefore, as illustrated in line 4, of FIG. 5, the step of checking whether there is a resource conflict may be performed by searching a column c with conflicting test groups T_{jC} and Tⱼc. In other words, each test group within a column or temporally overlapping time interval will be compared to each other test group in the same column, whether there is a resource conflict so that the number of available test resources in a column is lower than the number of actually required test resources within the column. The search to find a column c with conflicting test groups may be performed column-by-column until all resources conflicts are eliminated or until no resource conflict can be found.

In one embodiment, the step of checking whether there is a resource conflict, as illustrated in step 20 of FIG. 1, and the step of manipulating the execution order of the test groups, as illustrated in step 30 of FIG. 1, may be repeated until each resource conflict is eliminated. This repetition may be implemented in the pseudo-code by the do-while loop in lines 4 and 5 of FIG. 5. According to lines 6 and 7 of FIG. 5, two test groups TGⱼₓ and TG_{jC} are swapped if (“if”—instruction) another test group in the test flow of the conflicting test group can be found so that according to formula 4 the swap-operation of the test groups within the test flow does not create a new resource conflict. Manipulating the execution order of a test group in a test flow in response to the result of checking whether there is a resource conflict is performed, and a swap-operation is used in order to eliminate any resource conflicts. According to one exemplary embodiment, a swap-operation may only be performed when performing the swap-operation causes no new resource conflicts. If such a swap-operation with the test group TG_{jC} is not possible without creating a new resource conflict, then, according to lines 8 and 9 of FIG. 5, another test group TG_{jX} is searched which can be swapped with the other test group TGj_{C} related to the resource conflict. In other words, a swap-operation may be performed but this time within the test flow of the other conflicting test group TGj_{C} (see line 4).

According to one embodiment, the swap-operation may comprise a higher priority. The swap-operation may be preferably performed in order to eliminate a resource conflict. If neither of the resource conflicting test groups TG_{IC} and TG_{JC} may be swapped by means of a swap-operation (because such a swap-operation would result in a new resource conflict), a move-operation of the resource conflicting test group TG_{IC} to an empty position TG_{IZ} in the same row or the same test flow of the matrix arrangement should be performed. If this is not possible according to the other “else-if” instruction in lines 12 to 13 of FIG. 5, the same can be performed with the other conflicting test groups TG_{JC} and an empty position for test group TG_{JZ} in the respective test flow of the matrix arrangement.

The exemplary movement of a test group to a time interval or column of a test group which is empty may be named herein a move-to-empty-time-interval-operation. Such a move-to-empty-time-interval-operation may be performed with a lower priority than the swap-operation but with a higher priority compared to a time-interval-insert-operation in combination with a move-operation. The move-to-empty-time-interval-operation is only performed, as expressed by the condition “else-if” instruction in lines 10 and 12 of FIG. 5, and no new resource conflict (!(TG_{IC}⋄z) and !(TG_{JC}⋄z)) is created by moving the test group TG_{IC} or TG_{JC} to the new time interval or column position set. An empty time interval or column can be created, for example, by a preceding time-interval-insert-operation. Such a time-interval-insert-operation may be performed as described in lines 14 and 15 of FIG. 5 (an “else” instruction and an “insert column” instruction), if both the swap-operation and the move-to-empty-time-interval-operation cannot be performed due to the creation of a new resource conflict.

According to the exemplary embodiment in FIG. 5, the time-interval-insert-operation may be performed by inserting a new column c+1 and by moving the resource conflicting test group TG_{JC} to the newly inserted column or time interval TG_{J(C+1)}. According to this exemplary embodiment, by applying the time-interval-insert-operation a new column in the matrix arrangement may be inserted, e.g., in each test flow for each device under test a new overlapping empty time interval is inserted. Therefore, the test group associated with a resource conflict can be moved to the inserted column or time interval since there are no other test groups which might cause a new resource conflict.

In accordance with another exemplary embodiment, the time-interval-insert-operation may be restricted so that only in the test flow or row of the resource conflicting test groups TG_{IC} or TG_{JC} will a new time interval be inserted. This can be done, for example, by moving the resource conflicting test group to the end of the respective test flow. But it may also be possible to move the resource conflicting test groups to a different position within the test flow, if there is not a new resource conflict created. As illustrated in FIG. 5 by the sequence of the instructions, the different operations for eliminating a resource conflict may have a different priority. The swap-operations as illustrated in lines 7 and 9 of FIG. 5 may have a higher priority than the move-to-empty-time-interval-operation, as illustrated in lines 11 and 13 of FIG. 5, and the move-to-empty-time-interval-operation may have a higher priority than the time-interval-insert-operation in combination with the move-operation, as illustrated in line 15 of FIG. 5. In one exemplary embodiment, a higher priority means that such an operation is preferably performed compared to an operation with a lower priority.

The method for scheduling a use of test resources for the execution of test groups may comprise a loop or may be performed in a repeated manner until all resource conflicts are eliminated. This is illustrated by the “do while” loop in the pseudo-code illustrated in FIG. 5.

If the algorithm illustrated in FIG. 5, and described herein, is applied to the test flow arrangement illustrated in FIG. 3, a reordering of the test flows is performed which results in a more efficient test flow arrangement in terms of test resources and test times, as it is shown in FIG. 4.

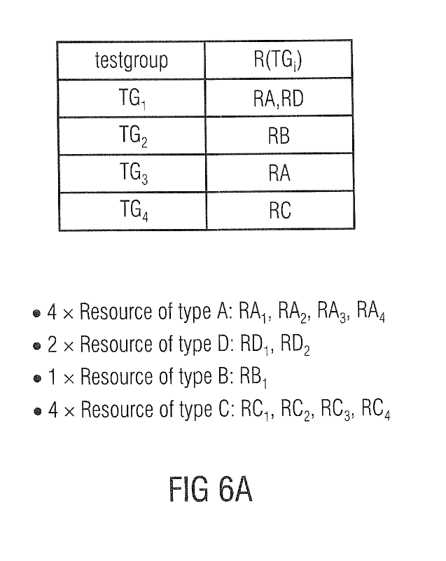

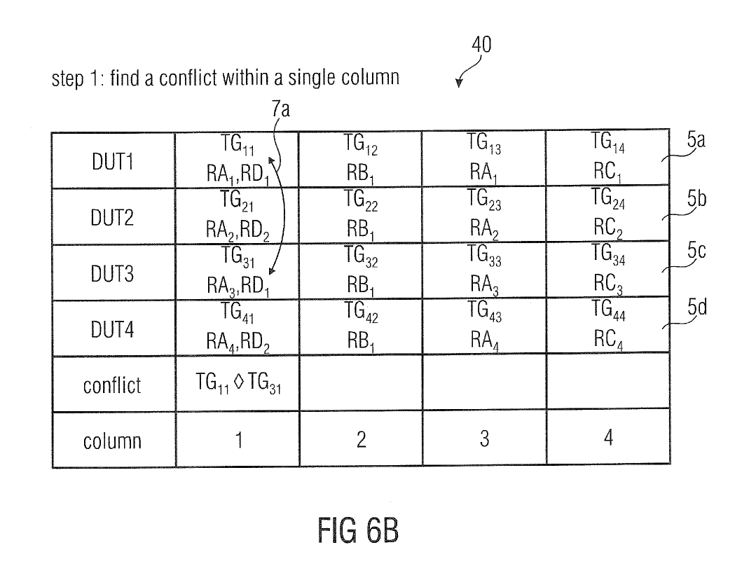

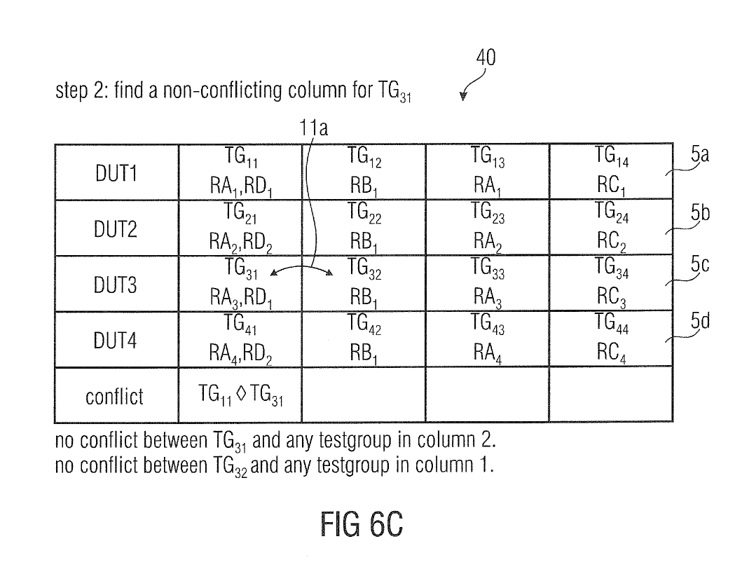

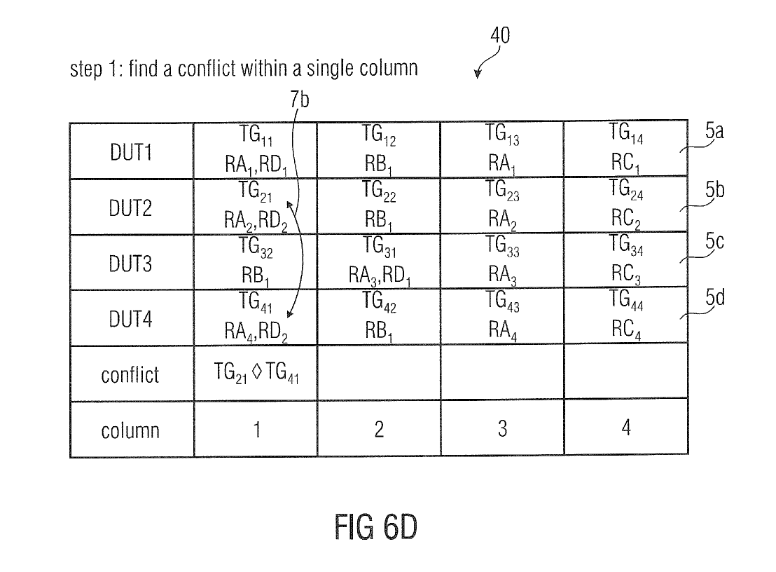

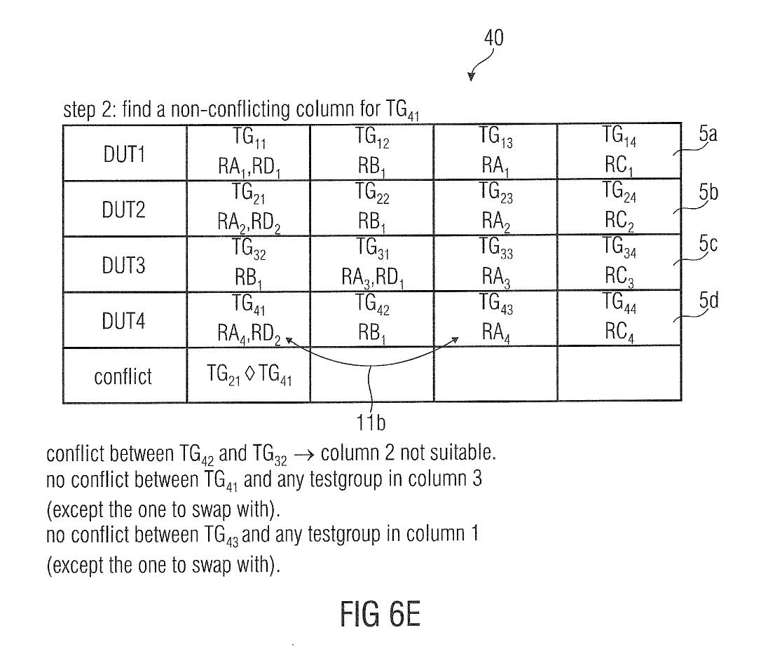

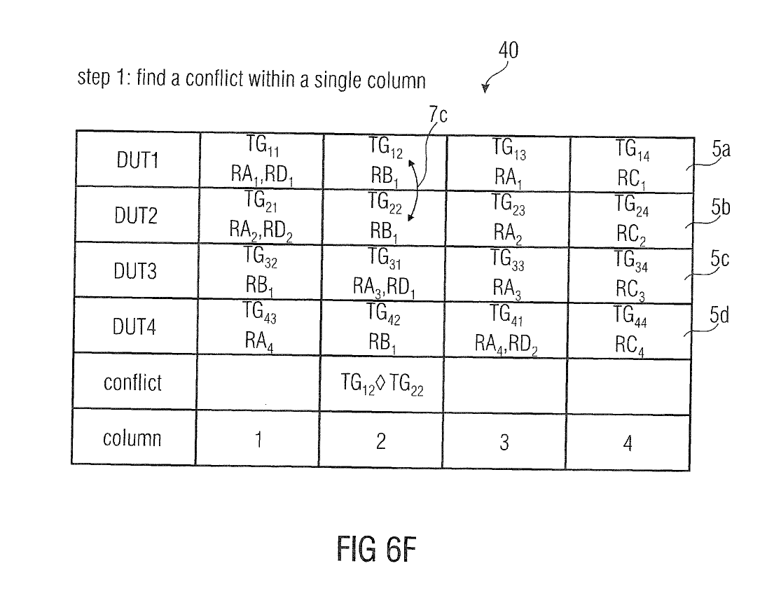

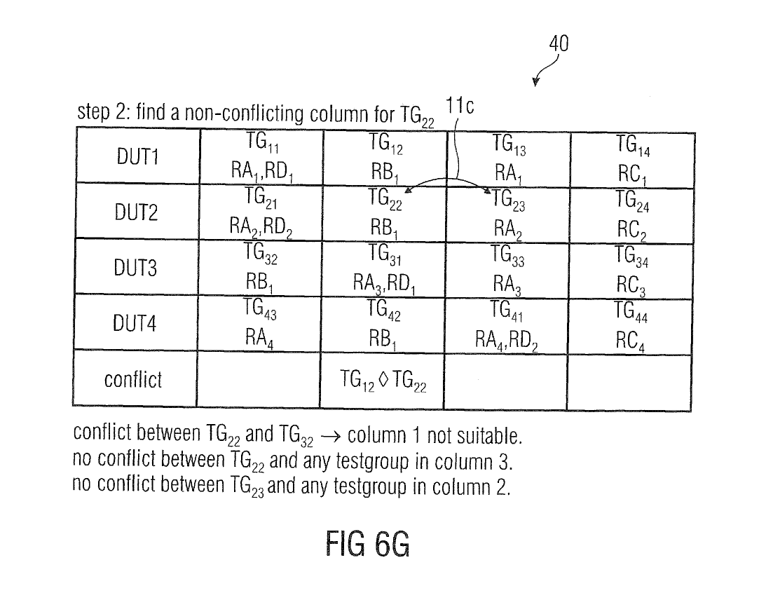

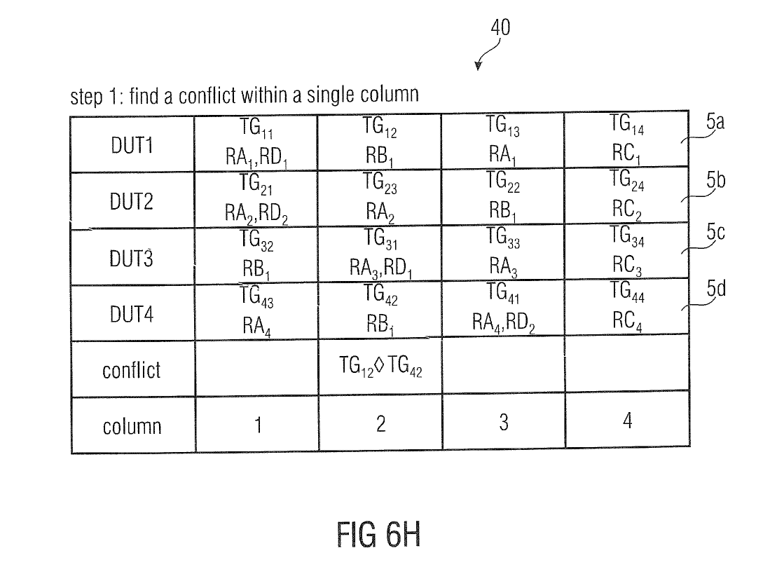

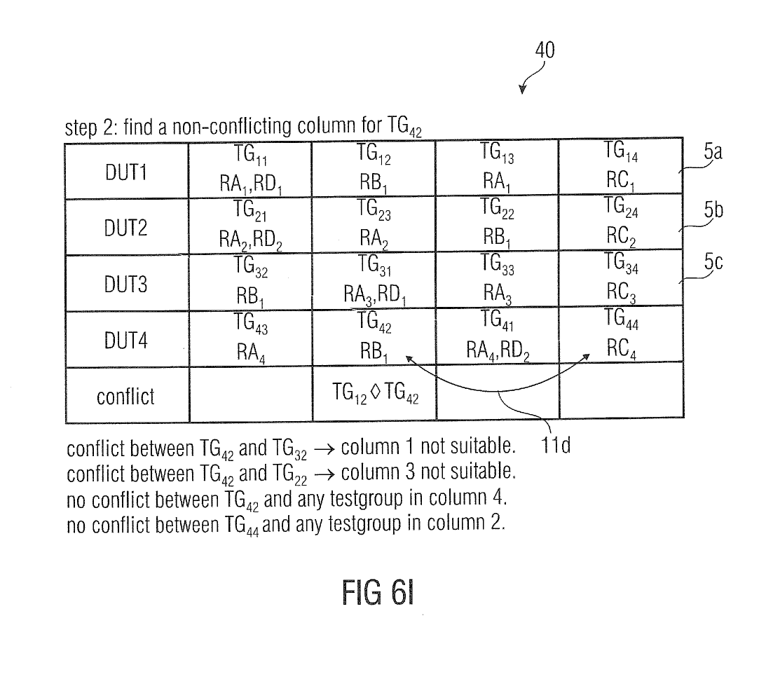

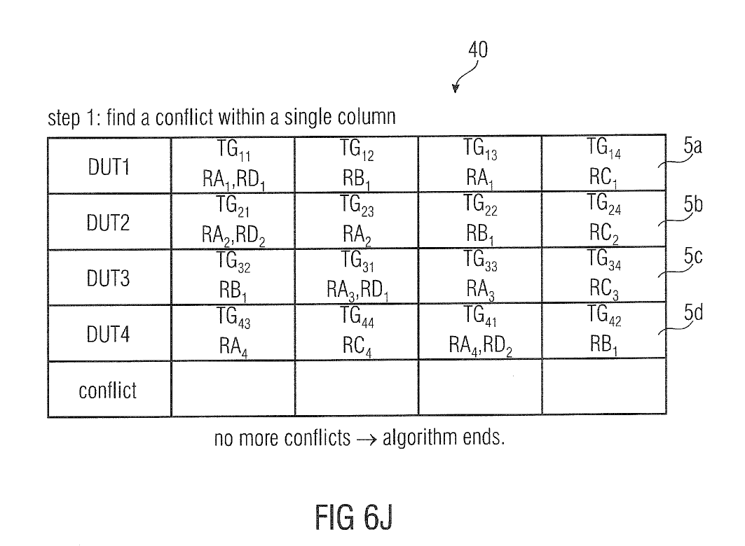

By means of the embodiments illustrated in FIGS. 6A through 6J, an exemplary execution of a process and an exemplary method for scheduling test resources of a test arrangement, as also illustrated in FIG. 1, may be described in detail. The method for scheduling a use of test resources of a test arrangement for the execution of test groups comprises a step of obtaining an assignment of a test resource of the test arrangement to a test group of a test flow, as illustrated in step 10 of FIG. 1. An initial test flow for the (test-) sites may contain the test groups shown in FIG. 6A. At least one test resource RA, RB, RC or RD may be assigned to each test group TG₁, TG₂, TG₃ and TG₄ as illustrated in Table 1 of FIG. 6A. Test group TG₁ requires the test resources RA and RD, test group TG₂ requires the test resource RB, test group TG₃ requires the test resource RA, and test group TG₄ requires the test resource RC. Furthermore, as it is shown in Table 2 of FIG. 6A, the test system or test arrangement may be assumed to provide four times the test resource of type A: RA₁, RA₂, RA₃, RA₄, two times the test resource of type D: RD₁ and RD₂, one time the test resource of type B: RB₁, and four times the test resource of type C: RC₁, RC₂, RC₃, RC₄. According to the embodiment the same test flow runs on 4 DUT sites in parallel.

In FIG. 6B, an exemplary matrix arrangement or two dimensional array 40 is illustrated. Four devices under test DUT 1, 2, 3, and 4, are tested in parallel. As illustrated in FIG. 6B, each row of the matrix arrangement may correspond to a test flow 5a, 5b, 5c, 5d, and each column 1,2,3,4 represents a time interval. In this exemplary embodiment each test flow may comprise the same test group in the same execution order. The test groups in the same columns are supposed to run or to be executed at the same time or the same time interval on the test arrangement. According to embodiments of the method, illustrated in FIG. 1, for scheduling a use of test resources based on the matrix arrangement, the step of checking whether there is a resource conflict between test groups in column 1 of the matrix arrangement is performed. In this embodiment a resource conflict 7a is given between the test groups TG₁₁ and TG₃₁ (TG₁₁ ⋄ TG₃₁). Since the test arrangement provides four times the test resources RA_{1,2,3,4}, there is no resource conflict between TG₁₁ and TG₃₁ concerning the test resource RA. But, since the test arrangement only provides one times the test resource RD at the same time, there is a resource conflict between the test group TG₁₁ and TG₃₁, where both require the test resource RD in the same column or time interval.

As illustrated in FIG. 6C, another test group may be searched within the row or test flow of one of the resource conflicting test groups TG₁₁, and TG₃₁, so that a swap-operation may be performed without creating a new resource conflict. According to the embodiment illustrated in FIG. 6C, manipulating may further comprise the step of searching a non-conflicting column for TG₃₁. In this embodiment column 2 is a non-conflicting column for TG₃₁. Therefore, a swap-operation 11a between test group TG₃₁ and test group TG₃₂ may take place. As a prerequisite for the swap-operation 11a, the step of checking whether there is a conflict between TG₃₁ and any other test group in column 2, and whether there is any conflict between test group TG₃₂ and any test group in column 1, may be performed first. Only if there is no conflict will a swap-operation 11a be performed.

FIG. 6D illustrates an exemplary situation after the swap-operation 11a has been performed. The test group TG₃₂ is now located in column 1 and the test group TG₃₁ is located at the former position or time interval of the test group TG₃₂ in column 2. This means the first resource conflict 7a, illustrated in FIG. 6B, between the test group TG₁₁ and the test group TG₃₁ in column 1, is eliminated by the swap-operation 11a illustrated in FIG. 6C.

In accordance with the exemplary method, illustrated in FIG. 1, for scheduling a use of test resources of a test arrangement for the execution of test groups, the step of checking whether there is a resource conflict between two test groups, is continued in a single column—here in column 1 of the matrix arrangement 40, as illustrated in FIG. 6D. A second resource conflict 7b is given in column 1 because both test group TG₂₁ and test group TG₄₁ require test resource RD₂ in the same column or time interval. The test arrangement provides two test resources of type D: RD₁ and RD₂, but in column 1 the test group TG₁₁ already requires the test resource RD₁. Therefore, there may be a resource conflict, if two further test groups TG₂₁ and TG₄₁ require the test resource RD₂ at the same time or in the same column.

In accordance with an exemplary method illustrated in FIG. 1, during the step of manipulating (step 30), first the step of searching a non-conflicting column for TG₄₁ within the same test flow 5d is performed. The step of searching a non-conflicting column may comprise one or more steps of checking (step 20), whether a swap-operation is possible between test groups in other columns of the test flow without creating a new resource conflict by this swap-operation.

As illustrated in FIG. 6E an exemplary swap-operation or a change of the positions of the test groups TG₄₁ and Ta₄₂ (column 2) should not be performed or is not allowed since the test group TG₄₂ and the test group TG₃₂ would create a new resource conflict regarding the test resource RB₁. In other words, there may be a new conflict between TG₄₂ and TG₃₂, and hence column 2 would not be suitable for a swap-operation with TG₄₁. According to the exemplary method, column-by-column is now checked to determine if a swap-operation is possible. Since there exists no conflict between the test group TG₄₁ and any test group in the subsequent column 3, except for the test group to swap with, and there also exists no conflict between the test group TG₄₃, the possible swapping target and any test group in column 1, except the test group to swap with, a swap-operation between both test groups may be performed in order to eliminate the resource conflict 7b. Therefore, in FIG. 6F, the test group TG₄₃ may be moved or placed at the former position of the test group TG₄₁ in column 1 and the test group TG₄₁ may be placed at the former position of the test group TG₄₃ in column 3. Since there is no further resource conflict in column 1 of the test arrangement 40, the step of checking whether there is a resource conflict between test groups in a column (step 20 of FIG. 1) is continued in the next column 2 of the test arrangement 40. In column 2 a further resource conflict 7c between test group TG₁₂ and test group TG₂₂ is illustrated. As described above, in FIG. 6G, a non-conflicting column 3 for the test group TG₂₂ in the same test flow or row 5b is again searched. A swap-operation between the test group TG₂₂ and the test group TG₂₁ in column 1 of row 5b is not possible or allowed since a new resource conflict between TG₂₂ in column 1 and the test group TG₃₂ concerning the test resource would be created. Therefore, the search to find a non-conflicting column or test group TG₂₂ is continued within the remaining columns 3 and 4. Since there is no conflict between the test group TG₂₂ and any other test group in column 3 of the test matrix 40, and furthermore, there is also no conflict between the test group TG₂₃ and any other test group in column 2, a swap-operation 11c between the test groups TG₂₂ and TG₂₃ can be performed, as illustrated in FIG. 6G.

In FIG. 6H, by means of the swap-operation 11c, the resource conflict between the test groups TG₁₂ and TG₂₂ may be eliminated. The continuation of the step of checking (step 20 of FIG. 1) in column 2 reveals a further resource conflict between the test group TG₁₂ and the test group Ta₄₂ with respect to the test resource RB₁. In response to the positive result of checking (step 20) whether there is a resource conflict within column 2, manipulating (step 30) may be performed by searching first a non-conflicting column for test group Ta₄₂ in row 5d. Thus, checking may be performed in order to determine whether there would be a new resource conflict related to this operation. In the exemplary embodiment illustrated in FIG. 6I, there would be a conflict between the test group Ta₄₂ and the test group TG₃₂ in column 1. Therefore, column 1 is not suitable for a swap-operation. Also, column 3 is not suitable for a swap-operation because there would be a new resource conflict created between the test group Ta₄₂ and TG₂₂ with respect to the test resource RB₁. However, a swap-operation between the test group Ta₄₂ and the test group TG₄₄ in the test flow or row 5d is possible. Checking for resource conflicts reveals that there is no conflict between the test group Ta₄₂ and any other test group in column 4 of the matrix arrangement 40, and that there is also no conflict between the test group TG₄₄ and any test group in column 2. Therefore, a swap-operation 11d between the test group Ta₄₂ and the test group TG₄₄ may be performed.

In FIG. 6J, an exemplary final test matrix arrangement is illustrated after performing the swap-operation 11d between the test group Ta₄₂ and the test group TG₄₄. The step of checking whether there is a resource conflict between test groups in a column of the matrix arrangement is continued. If no further resource conflict between test groups within a single column or time interval exists, the algorithm ends and the method for scheduling test resources of a test arrangement is finished.

In accordance with exemplary embodiments of the method illustrated in FIG. 1, the steps of checking whether there is a resource conflict, illustrated in step 20 of FIG. 1, and manipulating the execution order of the test groups, illustrated in step 30 of FIG. 1, are repeated until each resource conflict between an assignment of a test resource to a test group and an assignment of one or more test resources to another test group, which other test group is scheduled for temporally overlapping execution with the test group using the test arrangement is eliminated. A resource conflict may be given if the number of test groups with an assignment of an identical test resource, scheduled for temporally overlapping execution using a test arrangement, is higher than the number of identical test resources which can be made available by the test arrangement for temporally overlapping execution. According to one embodiment, the number of rows of the matrix arrangement 40 determines the number of devices under test scheduled for temporally overlapping execution using the test arrangement. The number of columns of the matrix arrangement 40 determines the number of test groups in a test flow for a DUT running on a test arrangement. According to other embodiments rows and columns and the corresponding operations can be swapped in other embodiments, e.g. the swap-operation is performed between two rows and so forth.

Both operations can be performed by swapping the column position of a test group associated with a resource conflict with another test group on another column position in the same row, if the test group associated with the resource conflict and the other test group at the column position of the test group associated with the resource conflict does not create a further resource conflict. A time-interval-insert-operation may be performed by inserting an additional column in the matrix arrangement 40. A subsequent move-operation may be performed by shifting the test group associated with the resource conflict to the inserted time-interval or column in the same row. A move-to-an-empty-time-interval-operation may be performed by moving a test group associated with the resource conflict to a column position which is not occupied by another test group in the same row of the matrix arrangement.

In step 30 of FIG. 1, manipulating the execution order of the test group in a test flow may further comprise electrically connecting a device under test to test resources of the test arrangement depending on the manipulated execution order.

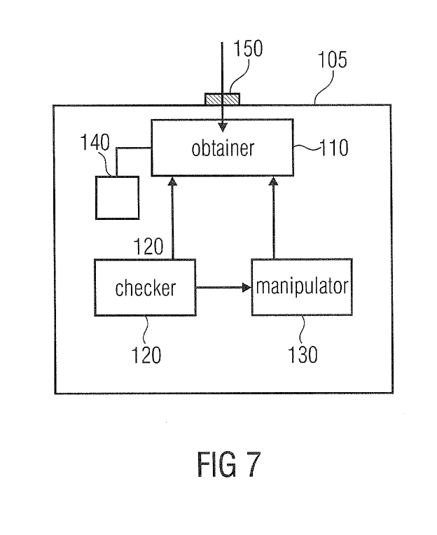

FIG. 7 illustrates an exemplary schematic block diagram of an apparatus 100 for scheduling test resources of a test arrangement. The apparatus 100 for scheduling test resources of a test arrangement may comprise an obtainer 110 for obtaining an assignment of a test resource of the test arrangement to a test group of a test flow for testing a device under test using the test arrangement. In one exemplary embodiment, the test flow comprises an initial execution order of the test groups. The apparatus 100 may also comprise a checker 120 for checking whether there is a resource conflict between the test resource assigned to a test group in a test flow and one or more test resources assigned to another test group in another test flow which the other test group is scheduled for temporally overlapping execution with the test group using the test arrangement. In response to the result of the checker 120, a manipulator 130 may be configured to manipulate the execution order of the test groups in a test flow. The manipulator 130 may be configured to eliminate a resource conflict by performing a swap-operation between a test group associated with the resource conflict in a test flow with a higher priority compared to a time-interval-insert-operation in combination with a move-operation, moving the test group associated with the resource conflict to an inserted time interval.

According to exemplary embodiments, an obtainer 110 may be configured to calculate itself or obtain, based on a given set of test groups and test resources for the test arrangement, an assignment of a test resource to each test group of a test flow. According to another embodiment the obtainer 110 may be configured to obtain externally, i.e. from an external facility or person, an assignment of a test resource to a test group of a test flow for testing a device under test using the test arrangement. For that, the obtainer 110 may further comprise a communication interface 150 to the environment. The communication interface 150 may be a computer interface, a keyboard and so forth. Furthermore, according to exemplary embodiments, the apparatus 100 may comprise a memory 140 which is configured to store at least temporally the execution order of the test groups in a test flow.

The manipulator 130 may be configured to perform in addition to a swap-operation and a time-interval-insert-operation in combination with a move-operation, a so-called move-to-empty-time-interval-operation. The manipulator 130 may be configured to perform the move-to-empty-time-interval-operation with a lower priority than a swap-operation, but with a higher priority than the time-interval-insert-operation in combination with the move-operation. An operation with a higher priority may be performed before an operation with a lower priority or an operation that is preferred in terms of time. According to further embodiments, the apparatus 100 for scheduling test resources may comprise a further means to electrically connect or electrically disconnect devices under test on the test system or test arrangement depending on the scheduled test resources. Such means can be, for example, a switch matrix in a tester which may be used to switch electrical connections to different DUTs depending on the execution order of the test groups to different test resources of a test arrangement or test system. With such a switch matrix it may be possible to test a plurality of devices under test in parallel or in temporally overlapping time intervals and to schedule a use of the available test resources of a test arrangement.

In further embodiments, the exemplary method illustrated in FIG. 1, and discussed herein, may comprise an additional step which can be performed before the step of checking whether there is a resource conflict between assignments of test resources is executed. In this preceding step to each instance of a test group, an instance of the required test resource type is assigned. This can be done, for example, by a person, e.g. a test designer or a test engineer, who determines which instrument (type or instance) is required for testing a DUT. In one exemplary embodiment, a resource conflict may only occur between two test groups which want to make use of the same instance of a test resource at the same time.

According to another embodiment of the method for scheduling a use of test resources of a test arrangement for the execution of test groups, the assignment between instances of the test groups and test resources are not given but may be determined dynamically. This may be achieved, for example, during testing, so that test resources which can be allocated in a certain time interval are dynamically scheduled for tests which are executed at a certain moment. This means, depending on the executed tests or test groups, the test resources of a test arrangement may be allocated to the test groups dynamically during the test time.

According to a further aspect of the exemplary method illustrated in FIG. 1, and the apparatus 100 illustrated in FIG. 7, the definition of a test resource may influence the test time for testing the devices under test. In general, a minimal and a maximal granularity may be given by the necessary parallel usability of the test resources. Considering a complete test system as a test resource may cause a constraint serialization of the whole test procedure. If the definition of a test resource is too fine, for example, single devices of an analog instrument of a test arrangement, the algorithm could run slowly although no better utilization compared to a more coarse grain definition of the test resource assignment would be achieved.

According to exemplary embodiments, each instrument in a test system or test arrangement may be considered as a test resource which can be assigned to a test group in a test flow for testing a device under test. In general, the calculation time or the time the method needs for scheduling test resources of a test arrangement may strongly depend on the number of test resources which have to be taken into account. Therefore, for example, all digital channels which are assigned to the same site may be grouped together as a single test resource which can be assigned to a certain test group. This may also apply to all instruments which are fixedly assigned to a (test-) site or test arrangement since those instruments should not have a test resource conflict since they exist only one time per site. The algorithm or the method for scheduling a use of test resources may also optimize the execution order for shared test resources.

According to another exemplary embodiment of the method of FIG. 1, step 10 of FIG. 1, obtaining an assignment of a test resource, may be performed by logically arranging the test groups in a fixed scheme or pattern—the matrix arrangement—wherein the actual duration or test time of each single test group is not considered. In other words, there are fixed time intervals which act as placeholders for test groups. The fixed time intervals are not related to an actual time duration of a test group. At the beginning, such a matrix arrangement may not comprise fixed empty time intervals. Empty time intervals in the matrix arrangement may develop if there is a resource conflict which cannot be solved by a swap-operation, and hence a time-interval-insert-operation is performed which creates a new column in the matrix arrangement, and therewith empty time intervals. Nevertheless, if a fixed scheme or matrix arrangement without any empty time intervals is given, it may comprise some “time gaps” due to a possible shorter test time duration of a test group compared to the time duration of the fixed time intervals.

According to another exemplary embodiment, each fixed time interval of a matrix arrangement may, for example, comprise a certain time duration of, e.g. 1 minute, and hence if a test group requires only half a minute test time, the residual half minute forms a “time gap”. In one exemplary embodiment, a fixed time interval does not comprise a fixed time duration. The time interval is not specified in terms of duration while reordering test groups. After reordering, each time interval may be assigned a duration, for example, the duration may be assigned according to the longest test group run time within the interval if the durations of those test groups are known in advance. If the duration is unknown the exemplary apparatus or algorithm may start the tests of one time interval in parallel and wait for all of them to finish before starting the test groups assigned to the subsequent time interval.

According to other exemplary embodiments, the method for scheduling a use of test resources can be performed or can use an algorithm which can by means of multithreading and a suitable resource driven scheduling, optimize the scheduling of test resources with respect to the above mentioned “time gaps.” According to other embodiments described herein, the varying run time or time duration of each single test group may be considered if the exemplary method for scheduling a use of test resources of a test arrangement is performed. The time duration of a time interval or a column of a matrix arrangement may be adapted to the different time durations of the test groups arranged in the matrix.

In further exemplary embodiments, a schedule of the use of test resources can be achieved before the testing of the DUTs starts, or according to further embodiments, the use of test resources may be scheduled during the testing of the DUTs. In other words, the schedule of a use of test resources may be achieved instantaneously or “on demand” or dynamically. The test resources may be allocated to test groups which are going to be executed next or soon. Since the exemplary embodiments consider scheduling test execution at run time as well, it should be noted that this, consideration of variable test times of individual test groups may be more efficient. The time-sliced approach, with fixed time intervals, may provide better reproducibility since it can be calculated upfront. Depending on certain test requirements the one or the other approach may be considered more advantageous.

Therefore in some embodiments an assignment of a test resource of the test arrangement may be dynamically performed during testing of the DUTs, so that a time point at which a test resource is assigned to a test group is variable during a testing.

The above described embodiments are merely illustrative for the principals of the present invention. It is understood that modifications and variations of the matrix arrangement and the steps for performing the exemplary method will be apparent to others skilled in the art. It is the intent, therefore, to be limited only be the scope of the pending patent claims and not by the specific details presented by way of description and explanation of the embodiments therein.

The figures are illustrated as schematic block diagrams of the method for scheduling a use of test resources of a test arrangement for the execution of test groups. These figures simultaneously are an illustration of the exemplary apparatus, where the block functionalities are executed by certain parts or means for performing the functionalities.

Depending on certain implementation requirements of the exemplary methods, the exemplary methods described herein may be implemented in hardware or in software. The implementation may be performed using digital storage media. In other words, the inventive methods may be a computer program or an algorithm having a program code or pseudo code for performing at least one of the exemplary methods when the computer program or algorithm runs on the computer.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

What is claimed is:

1. A method of scheduling use of test resources of a test arrangement for the execution of test groups, the method comprising:
obtaining an assignment of a test resource of the test arrangement to each test group of a test flow for testing a device under test using the test arrangement, wherein the test flow comprises an initial execution order of the test groups;
checking whether there is a resource conflict between an assignment of a test resource to a given test group in a given test flow and an assignment of one or more test resources to other test groups in other test flows, wherein other test groups are scheduled for an overlapping execution with the given test group using the test arrangement; and
manipulating execution order of the test groups in a test flow in response to a result of the checking whether there is a resource conflict, wherein resource conflict is eliminated by:
performing a swap-operation between a test group associated with the resource conflict in a test flow with a higher priority compared to performing a time-interval-insert-operation in combination with a move-operation; and
moving the test group associated with the resource conflict to an inserted time interval.

2. The method according to claim 1, wherein the performing a time-interval-insert-operation is performed in the given test flow and in the other test flows so that the given test flow and the other test flows each comprise an inserted time interval, after the time-interval-insert-operation.

3. The method according to claim 1, wherein the manipulating the execution order of the test groups in a test flow further comprises executing a move-to-empty-time-interval-operation of a test group associated with the resource conflict to an inserted time interval, inserted previously using a time-interval-insert-operation in combination with a move-operation, and wherein the move-to-empty-time-interval-operation has less priority than a swap-operation, but a higher priority than the time-interval-insert-operation in combination with a move-operation.

4. The method according to claim 1, wherein the checking whether there is a resource conflict and manipulating the execution order of the test groups are repeated until each resource conflict between an assignment of a test resource to a given test group and an assignment of one or more test resources to other test groups, which other test groups are scheduled for an overlapping execution with the given test group using the test arrangement, are eliminated.

5. The method according to claim 1, wherein each test group comprises at least one test for testing a device under test, and wherein the given test flow for testing a given device under test using the test arrangement comprises a different test group compared to the test groups in the other test flows for testing other devices under test using the test arrangement and/or a different number of test groups.

6. The method according to claim 1, wherein a resource conflict exists if the number of test groups with an assignment of an identical test resource, scheduled for an overlapping execution using the test arrangement is higher than a number of identical test resources available in the test arrangement for a temporally overlapping execution.

7. The method according to claim 1, wherein the obtaining an assignment of a test resource comprises logically arranging each test group with an assignment of a test resource in a matrix arrangement, so that the test groups of the test flows for testing a device under test form rows and test groups, which are scheduled for overlapping execution using the test arrangement, form columns of the matrix arrangement, so that each test group comprises a column position and a row position in the matrix arrangement.

8. The method according to claim 7, wherein the number of rows of the matrix arrangement determines the number of devices under test, scheduled for an at least partly overlapping execution using the test arrangement, and wherein the number of columns of the matrix arrangement determines the number of time intervals for the test groups in a test flow for testing a device under test scheduled for an overlapping execution using the test arrangement.

9. The method according to claim 7, wherein the checking whether there is a resource conflict is performed column-by-column or row-by-row.

10. The method according to claim 7, wherein the swap-operation is performed by swapping the column position of a given test group associated with the resource conflict with the column position of another test group in the same row if the given test group at the column position of the other test group and the other test group at the column position of the given test group does not create another resource conflict.

11. The method according to claim 7, wherein a time-interval-insert-operation is performed by inserting an additional column in the matrix arrangement, and wherein a move-operation is performed by moving a given test group associated with the resource conflict to the column position of the additional column in the same row.

12. The method according to claim 7, wherein a move-to-empty-time-interval-operation is performed by moving the given test group associated with the resource conflict to an empty column position not occupied by another test group in the same row.

13. A method of testing a plurality of devices under test, the method comprising:
obtaining an assignment of a test resource of a test arrangement to each test group of a test flow for testing a device under test using the test arrangement, wherein the test flow comprises an initial execution order of test groups;
checking whether there is a resource conflict between an assignment of a test resource to a given test group in a given test flow and an assignment of one or more test resources to other test groups in other test flows, wherein the other test groups are scheduled for overlapping execution with the given test group using the test arrangement;
manipulating execution order of the test groups in a test flow in response to the checking whether there is a resource conflict, wherein resource conflict is eliminated by:
performing a swap-operation between a test group associated with the resource conflict in a test flow with a higher priority compared to performing a time-interval-insert-operation in combination with a move-operation; and
moving the test group associated with the resource conflict to an inserted time interval; and
electrically connecting and/or disconnecting the plurality of devices under test to test resources of the test arrangement based on the execution order of the test groups in the test flows.

14. The method according to claim 13, wherein the test arrangement comprises test resources configured to perform a test for a device under test by applying a test signal or a supply signal and/or to receive a device signal from the device under test, and wherein the test arrangement is configured to evaluate the device signal from the device under test to determine whether the device under test is passing the test or failing the test.

15. The method according to claim 13, wherein the test resources comprise at least one of a digital test channel, an analog test channel, an arbitrary waveform generator, a digitizer, a device power supply, and a radio frequency instrument.

16. The method according to claim 15, wherein at least one of the digital test channel, analog test channel, arbitrary wave form generator, digitizer, device power supply and radio frequency instrument are grouped together with another one of the digital test channel, analog test channel, arbitrary wave form generator, digitizer, device power supply and radio frequency instrument to form a test resource for an assignment of a test resource of the test arrangement to a test group.

17. The method according to claim 13, wherein the obtaining an assignment of a test resource of the test arrangement is dynamically performed while testing the plurality of devices under test, so that a time point at which a test resource is assigned to a test group is variable during testing.

18. An apparatus for scheduling test resources of a test arrangement, the apparatus comprising:
an obtainer module for obtaining an assignment of a test resource of the test arrangement to a test group of a test flow for testing a device under test using the test arrangement, wherein the test flow comprises an initial execution order of the test groups;
a checker module for checking whether there is a resource conflict between a test resource assigned to a given test group in a given test flow and one or more test resources assigned to other test groups in other test flows, wherein the other test groups are scheduled for overlapping execution with the given test group using the test arrangement; and
a manipulator module for manipulating execution order of the test groups in a test flow in response to the checker module, wherein resource conflict is eliminated by:
performing a swap-operation between a test group associated with the resource conflict in a test flow with a higher priority compared to performing a time-interval-insert-operation in combination with a move-operation; and
moving the test group associated with the resource conflict to an inserted time interval.
